(19) United States
(12) Patent Application Publication
(10) Pub. No.: US 2005/0186703 A1
(43) Pub. Date: Aug. 25, 2005

(54) Method for packaging semiconductor chips and corresponding semiconductor chip system

(76) Inventors: Kurt Weiblen, Metzingen (DE); Hubert Benzel, Pliezhausen (DE); Stefan Pinter, Reutlingen (DE); Roland Guenschel, Reutlingen (DE); Frieder Haag, Wannweil (DE)

Correspondence Address: KENYON & KENYON, ONE BROADWAY, NEW YORK, NY, 10004, US

(21) Appl. No.: 11/041,157

(22) Filed: Jan. 21, 2005

(30) Foreign Application Priority Data
Jan. 23, 2004 (DE) 10 2004 003 413.3

(51) Int. Cl. H01L 21/50

(52) U.S. Cl. 438/106

(57) ABSTRACT

A method for packaging semiconductor chips and a corresponding semiconductor chip system. The method includes making available a semiconductor chip having a diaphragm region; providing a cap over the diaphragm region, while leaving the diaphragm region open; mounting the semiconductor chip on a support frame; and providing a molded housing around the semiconductor chip and at least a partial region of the support frame for packaging the semiconductor chip.

### FIELD OF THE INVENTION

The present invention relates to a method for packaging semiconductor chips and a corresponding semiconductor chip system.

### BACKGROUND INFORMATION

Although applicable to any semiconductor chip systems, the present invention as well as the problem underlying it are explained with respect to a micromechanical semiconductor chip system having a pressure sensor.

FIG. 9 shows an example of a method for packaging semiconductor chips and a corresponding semiconductor chip system in a cross-sectional view.

In FIG. 9, reference numeral 100 denotes a TO8 base produced, for example, from Kovar. Reference numeral 5 is a micromechanical silicon pressure-sensor chip having piezoresistive transducer elements 51 that are accommodated on a diaphragm 55. To produce diaphragm 55, a cavity 58 is introduced onto the back of respective silicon pressure-sensor chip 5, for instance, by anisotropic etching, e.g., using KOH or TMAH. Alternatively, diaphragm 55 may also be produced by trench-etching.

Sensor chip 5 may be made up of a pure resistance bridge having piezoresistive resistors, or may be combined with an evaluation circuit which is integrated, together with the piezoresistors, in a semiconductor process. A glass base 140 made of sodium-containing glass, which is anodically bonded to the back of chip 5, is used to reduce mechanical stress caused by solder or adhesive 70 by which glass base 140 is mounted on TO8 base 100. Reference numeral 53 in FIG. 9 denotes a bonding pad of an integrated circuit 52 (not further shown), the bonding pad being connected via a bonding wire 60 to an electrical connecting device 130, which in turn is insulated from TO8 base 100 by an insulating layer 131. Glass base 140 has a through hole 141 which connects cavity 58, via a through hole 101 of TO8 base 100 and a connecting device 120 affixed thereon, to externally prevailing pressure P. The construction shown in FIG. 9 is usually also hermetically welded with a metal cap (not shown).

An alternative method is to cement sensor chip 5 onto a ceramic or into a premolded housing, and to passivate it with a gel for protection against environmental influences.

However, such designs have the disadvantage that they are complicated, and problems often occur with respect to hermetically enclosing sensor chip 5, e.g., because of permeable welded seams, etc. Since the TO8 housing and the silicon have different temperature expansion coefficients, mechanical stresses develop in response to temperature changes that are measured as interference signals by piezoresistors. When using a gel, the maximum pressure is determined by the gel.

European Patent No. 0 742 581 A2 describes a semiconductor chip system in which a semiconductor chip having a diaphragm region is sealed by a cap, the diaphragm region remaining free. In that case, the cap is anodically bonded to the semiconductor chip. The anodic bonding is disadvantageous in that no circuit structures can be located in the underlying silicon; only possibly doped regions for the leads are possible there.

### SUMMARY

In contrast to the conventional design approaches, an example method of the present invention for the packaging of semiconductor chips and the corresponding semiconductor chip system may have the advantage that they make it possible to mold around or extrusion-coat a semiconductor chip having a diaphragm region, e.g., a sensor chip. These housings, already used for years for standard ICs, are very cost-effective and simple to produce.

In accordance with an embodiment of the present invention, a cap is provided above the diaphragm region, which is mounted in the periphery of the diaphragm region and mechanically stabilizes the diaphragm region and at the same time provides protection from the molding material. All in all, an improved media resistance also results from the extrusion coating. The material of the cap is a matter of choice; preferably it is made of silicon. An advantage is therefore that the sensor chip and the cap have the same temperature expansion coefficients, resulting in fewer temperature effects in the output signal.

A further advantage may be the possible dispensing with the passivating gel on the diaphragm. On one hand, this results in less cross sensitivity with respect to accelerations. On the other hand, high application pressures are possible in the case of pressure from the front side (circuit side).

The present invention may make it possible to retain customary manufacturing processes of sensor chips, like, for instance, the semiconductor process for the piezoresistors and/or producing the evaluation circuit on the chip or the use of existing sensor housing parts.

An adjustment at the end of the production line is also possible after the molding process of the present invention, since burning segments made of aluminum may be opened in the circuit via the bonding leads. Optionally, a layer may be applied on, or a hollow space provided at, the burning segments, in order to absorb the vaporizing metal.

Electrical dice testing is possible in the wafer composite construction. Testing for impermeability may be performed both in conjunction with the electrical dice testing and upon final inspection. Optionally, pressure may be stored prior to the measurement.

According to one preferred further refinement, the cap is preferably mounted in the periphery of the diaphragm region using glass solder in such a way that a closed hollow space is formed between the cap and the diaphragm region. The cap may be secured on the chip by various methods, e.g., by adhesive bonding or preferably sealing glass soldering. The sealing glass soldering or adhesive bonding may also be implemented on circuit structures, which is very space-saving. Sealing glass bonding or adhesive bonding is suitable for step heights, i.e., topography differences in the region of the circuit. In the case of anodic bonding, on the other hand, a current must flow perpendicularly through the wafer. This is not possible in the circuit region.

According to another preferred embodiment, the cap has a through hole, the molded housing being provided in such a way that a through hole in the molded housing is connected to the through hole in the cap.

According to a further preferred refinement, the semiconductor chip is mounted on the support frame on the side opposite the diaphragm region.

According to another preferred embodiment, the support frame has a through hole that creates a connection to a cavity region below the diaphragm region, the molded housing being provided in such a way that a through hole in the molded housing is connected to the through hole in the support frame.

In another preferred development, the semiconductor chip is mounted on the support frame via a glass base that is secured on the back of the periphery of the diaphragm region.

According to a further preferred refinement, the semiconductor chip has a side edge region that projects laterally beyond the cap and has a bonding region that is electrically connected to the support frame via a bonding wire, the bonding wire being completely packaged in the molded housing.

In another preferred development, the cap has a through hole at which a connecting piece is mounted, the molded housing being provided in such a way that the connecting piece is partially packaged in the molded housing.

In another preferred development, the support frame has a through hole which creates a connection to a cavity region below the diaphragm region and at which a connecting piece is mounted, the molded housing being provided in such a way that the connecting piece is partially packaged in the molded housing.

According to a further preferred refinement, the semiconductor chip is mounted on the support frame via the cap.

In another preferred embodiment, the support frame is a leadframe.

According to another preferred development, prior to applying the semiconductor chip on a support frame and prior to providing a molded housing, a subassembly is formed including the semiconductor chip, the cap provided over the diaphragm region, and a glass base that is secured on the back of the periphery of the diaphragm region.

In another preferred embodiment, the subassembly is formed by the following steps:
making available a first wafer having a plurality of semiconductor chips in the composite construction;
making available a second wafer having a corresponding plurality of caps in the composite construction;
making available a third wafer having a corresponding plurality of glass bases in the composite construction;
joining the first, second and third wafers to produce a plurality of subassemblies in the composite construction; and
separating the subassemblies.

According to a further preferred development, the second wafer has a plurality of hollow spaces which, in joining the first and second wafers, leave open side edge regions that project laterally beyond the caps and have respective bonding regions; for separating the subassemblies, in a first sawing step, the second wafer is sawed over the hollow spaces for exposing the bonding regions, and in a second sawing step, the first and third wafers are sawed below the hollow spaces for separating the subassemblies, a larger saw-cut width being used in the first sawing step than in the second sawing step.

The bonding pads for the electrical contacting, which are completely covered after the encapsulation, can be exposed by this double sawing process. In this manner, no openings are necessary in the cap wafer which can be produced by micromechanical processes; the openings would make the cap wafer very fragile, thereby increasing the risk of cracking during handling.

### BRIEF DESCRIPTION OF THE DRAWINGS

Exemplary embodiments of the present invention are represented in the figures and explained in detail below.

FIG. 1 shows a first specific embodiment of an example method according to the present invention for packaging semiconductor chips and a corresponding semiconductor chip system in a cross-sectional view.

FIG. 2 shows a second specific embodiment of an example method according to the present invention for packaging semiconductor chips and a corresponding semiconductor chip system in a cross-sectional view.

FIG. 3 shows a third specific embodiment of an example method according to the present invention for packaging semiconductor chips and a corresponding semiconductor chip system in a cross-sectional view.

FIG. 4 shows a fourth specific embodiment of an example method according to the present invention for packaging semiconductor chips and a corresponding semiconductor chip system in a cross-sectional view.

FIG. 5 shows a fifth specific embodiment of the method according to the present invention for packaging semiconductor chips and a corresponding semiconductor chip system in a cross-sectional view.

FIG. 6 shows a sixth specific embodiment of an example method according to the present invention for packaging semiconductor chips and a corresponding semiconductor chip system in a cross-sectional view.

FIGS. 7a,b show a seventh specific embodiment of an example method according to the present invention for packaging semiconductor chips and a corresponding semiconductor chip system, and specifically, FIG. 7a in a cross-sectional view, and FIG. 7b in a plan view.

FIGS. 8a-g show successive method steps of an eighth specific embodiment of an example method according to the present invention for packaging semiconductor chips in a cross-sectional view.

FIG. 9 shows an example for a method of packaging semiconductor chips and a corresponding semiconductor chip system in a cross-sectional view.

### DESCRIPTION OF EXAMPLE EMBODIMENTS

In the Figures, components which are the same or functionally equivalent are denoted by the same reference numerals.

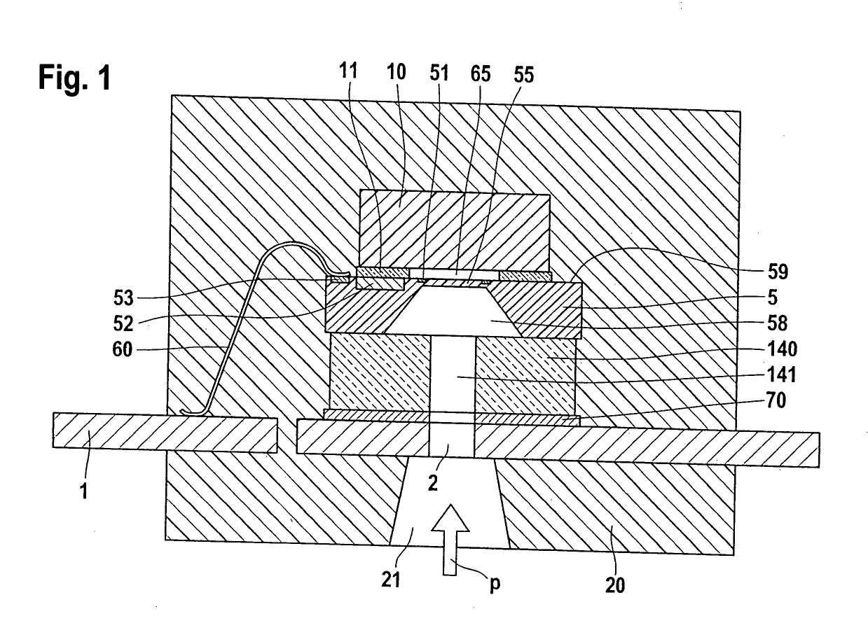

FIG. 1 shows a first specific embodiment of an example method according to the present invention for packaging semiconductor chips and a corresponding semiconductor chip system in a cross-sectional view.

In FIG. 1, reference numeral 1 denotes a leadframe on which a sensor chip 5, having a diaphragm region 55 and piezoresistors 51 located therein, is mounted via a glass base 140 and a solder layer 70. A cap 10 made of silicon is secured by a sealing glass layer 11 on sensor chip 5 in the periphery of diaphragm region 55. In the present example, sealing glass layer 11 is situated directly over integrated circuit 52 in sensor chip 5. A hollow space 65 is provided between cap 10 and diaphragm region 55. Reference numeral 53 denotes a bonding pad of an integrated circuit 52, the bonding pad being situated on a side edge region 59 of sensor chip 5 projecting laterally beyond cap 10. Bonding pad 53 is connected to leadframe 1 via a bonding wire 60.

Cavity 58 on the chip back side is connected via a through hole 141 to a through hole 2 in leadframe 1. A molded housing 20 is molded around the chip structure and a part of leadframe 1, molded housing 20 having a through hole 21 in the region of through hole 2, so that external pressure P can be applied from below to diaphragm region 55. Through hole 21 in molded housing 20 may be implemented by a punch during the molding process.

In the present case, cap 10 is unstructured (unpatterned) and leaves hollow space 65 between the diaphragm and its lower side open, which is easily attainable by sealing glass layer 11. Hollow space 65 allows diaphragm 55 to be deflected upward in the direction of cap 10 in response to pressure load. When mounting cap 10, a reference pressure or a reference vacuum is trapped in hollow space 65.

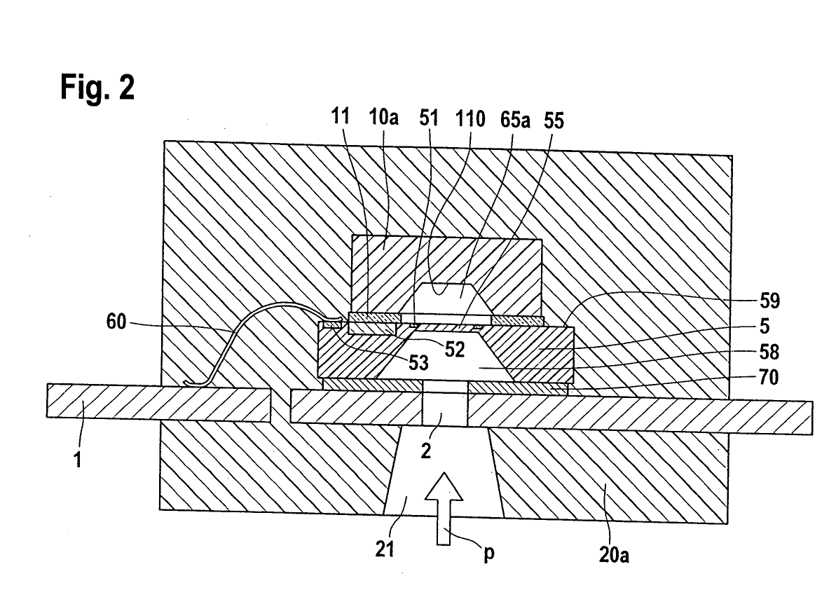

FIG. 2 shows a second specific embodiment of an example method according to the present invention for packaging semiconductor chips and a corresponding semiconductor chip system in a cross-sectional view.

In the set-up shown in FIG. 2, cap 10a, in the region of diaphragm 55, has a cutout 110 which permits an increase of the reference volume of hollow space 65a. A greater reference volume is advantageous for the long-term stability of the reference pressure. Structuring (not shown) of the outside of cap 10a would likewise be possible, in order to increase, for example, the distance to bonding pad 53.

Another difference of the semiconductor chip system shown in FIG. 2 in comparison to that according to FIG. 1 is that sensor chip 5 is soldered directly onto leadframe 1 using solder layer 70. The chip surface is strengthened by cap 10a in such a way that the mechanical stress, occurring in response to temperature changes at the connection to leadframe 1, is reduced. Dispensing with the glass base permits a lower-volume molded housing 20a.

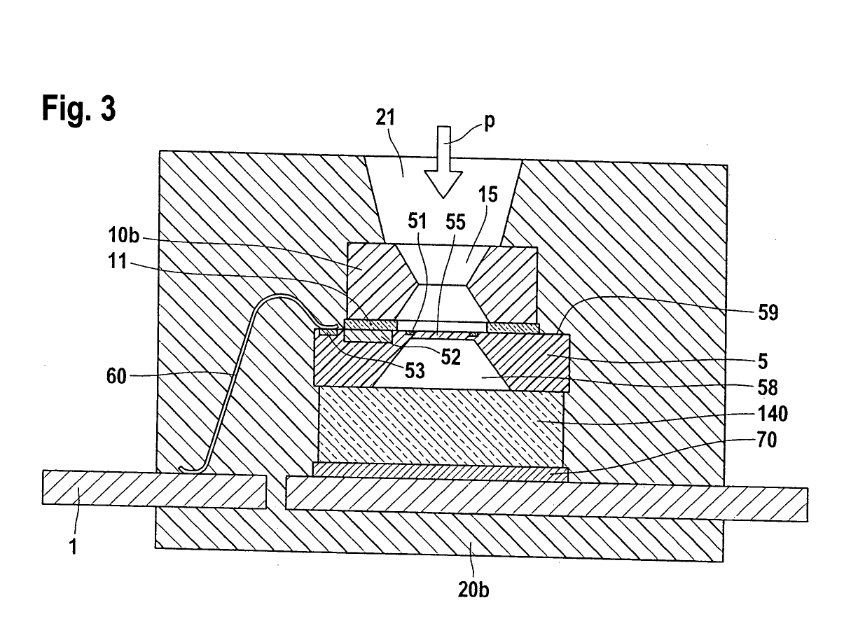

FIG. 3 shows a third example embodiment of the method according to the present invention for packaging semiconductor chips and a corresponding semiconductor chip system in a cross-sectional view.

In the third example embodiment shown in FIG. 3, cap 10b has a through hole 15, i.e., it has an annular shape. In this specific embodiment, the reference pressure is trapped in cavity 58, since the back of sensor chip 5 is sealed by a massive glass base 140, which in turn is joined to leadframe 1 via a solder layer 70. Through hole 21 situated above here in molded housing 20b may be implemented as in the other specific embodiments, by a suitable punch.

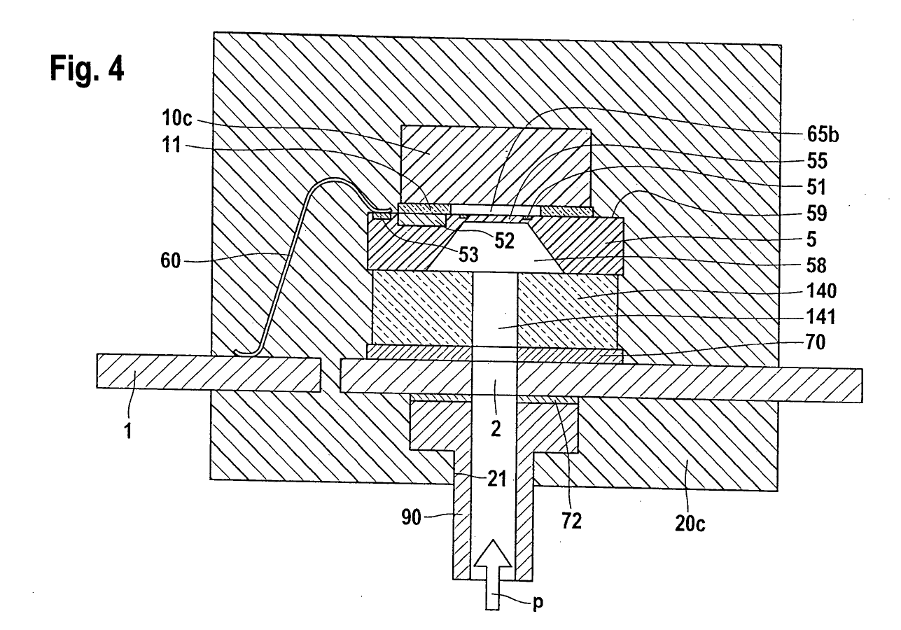

FIG. 4 shows a fourth example embodiment of the method according to the present invention for packaging semiconductor chips and a corresponding semiconductor chip system in a cross-sectional view.

Compared to the first example embodiment according to FIG. 1, in the example embodiment shown in FIG. 4, molded housing 20c is not interrupted by a punch during the manufacturing process; rather, a pressure connecting piece 90 has been joined by a solder layer 72 to leadframe 1 at through hole 2 prior to the molding process.

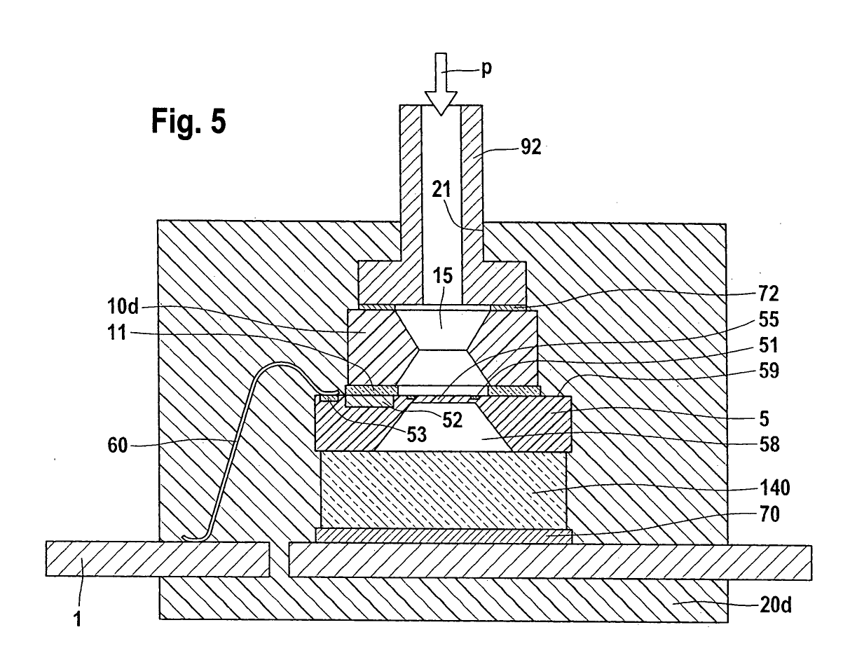

FIG. 5 shows a fifth example embodiment of the method according to the present invention for packaging semiconductor chips and a corresponding semiconductor chip system in a cross-sectional view.

In the example embodiment shown in FIG. 5, a pressure connecting piece 92 has been applied by a solder layer 72 on the upper side of the cap having through hole 15 prior to the molding process. Otherwise, this design is the same as that in the third example embodiment according to FIG. 3.

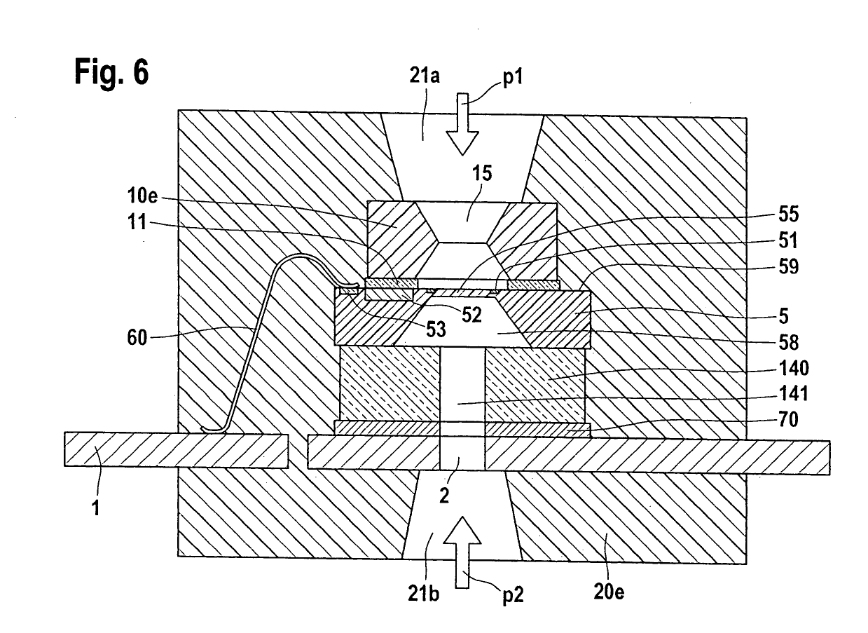

FIG. 6 shows a sixth example embodiment of the method according to the present invention for packaging semiconductor chips and a corresponding semiconductor chip system in a cross-sectional view.

The sixth example embodiment illustrated in FIG. 6 shows a differential-pressure or reference-pressure sensor, in which the pressure connection for pressures P1, P2 is effected from above and below. In other words, this design is a combination of the first and third specific embodiments. A combination of pressure connecting pieces 90 and 92 according to the fourth and fifth specific embodiments is possible as well.

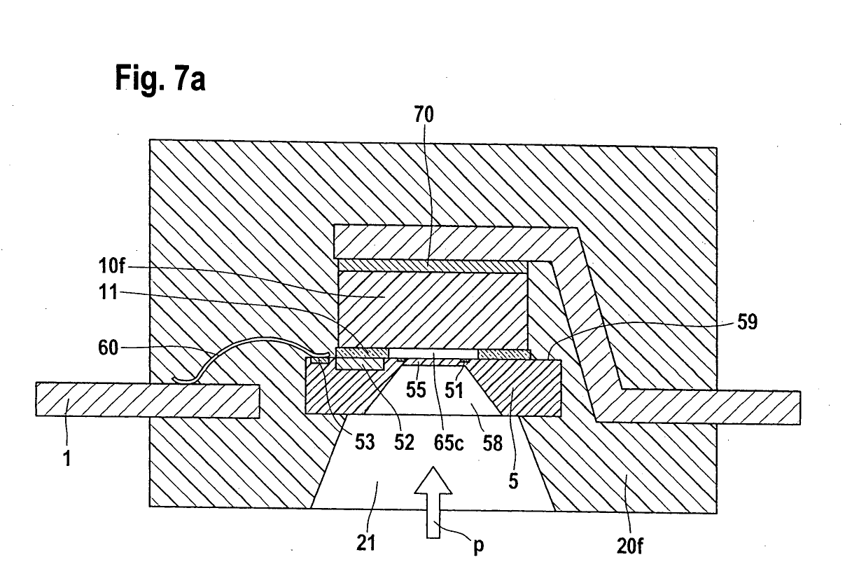

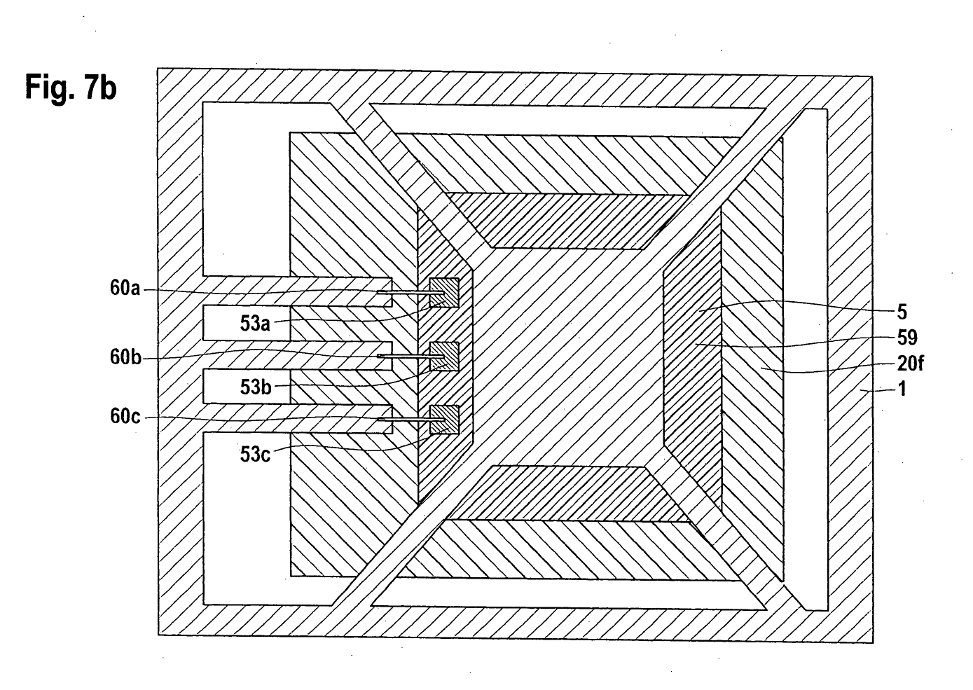

FIG. 7a,b show a seventh example embodiment of the method according to the present invention for packaging semiconductor chips and a corresponding semiconductor chip system in a cross-sectional view, and specifically, FIG. 7a in a cross-sectional view, and FIG. 7b in a plan view.

With reference to FIG. 7a, in this seventh example embodiment, the upper side of closed cap 10f is applied by way of an adhesive layer or solder layer 70 at a depression in leadframe 1. Optionally, in this example embodiment, a glass plate may also be applied to the lower side of sensor chip 5.

The representation according to FIG. 7b shows an upper view of the design layout of FIG. 7a, three adjacent bonding pads 53a, 53b, 53c being visible by way of example, which are connected to leadframe 1 via bonding wires 60a, 60b, 60c.

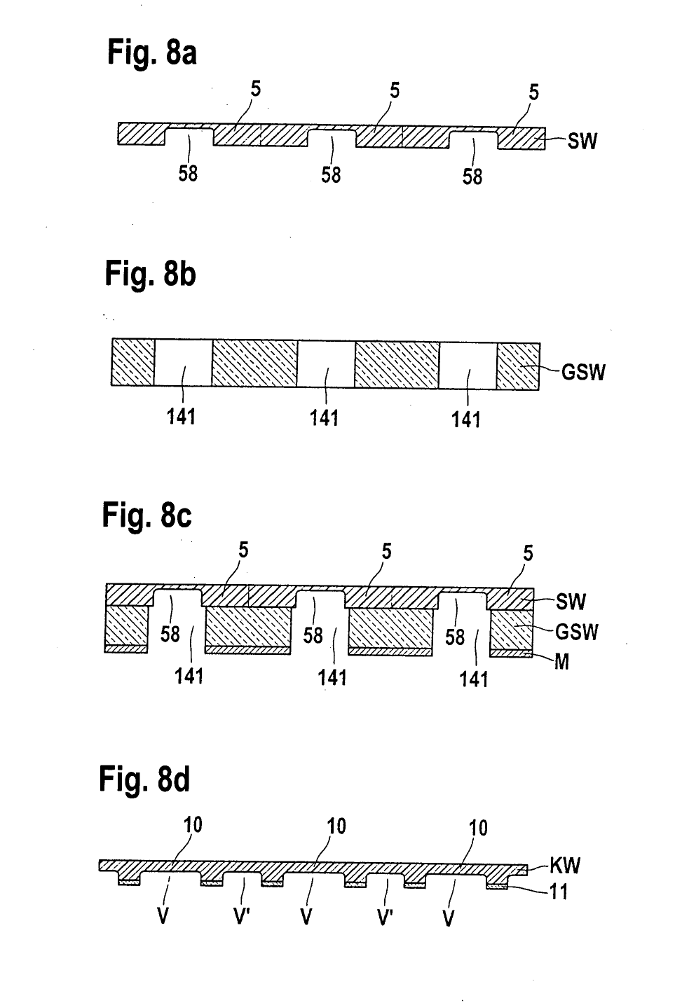

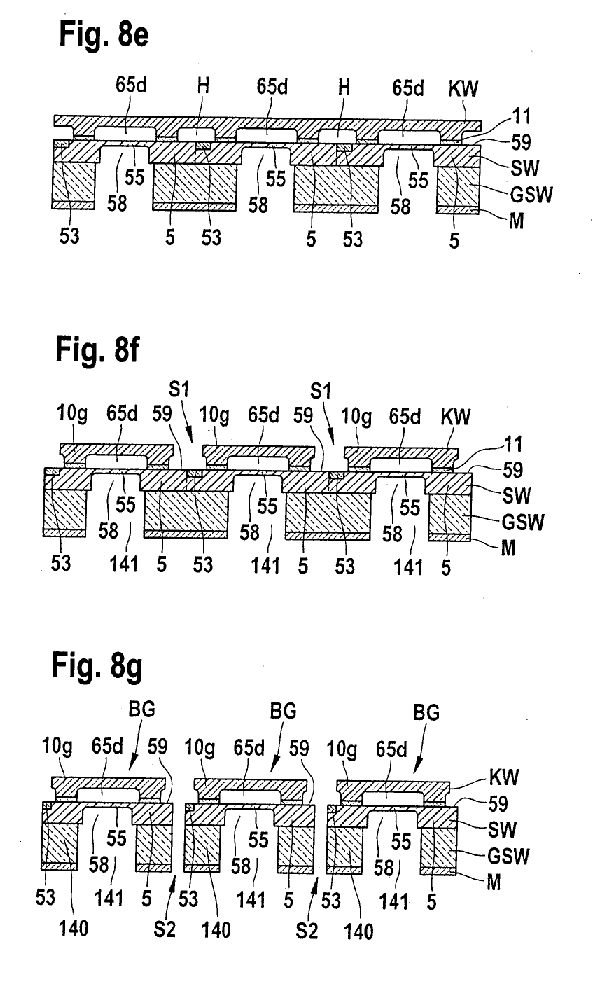

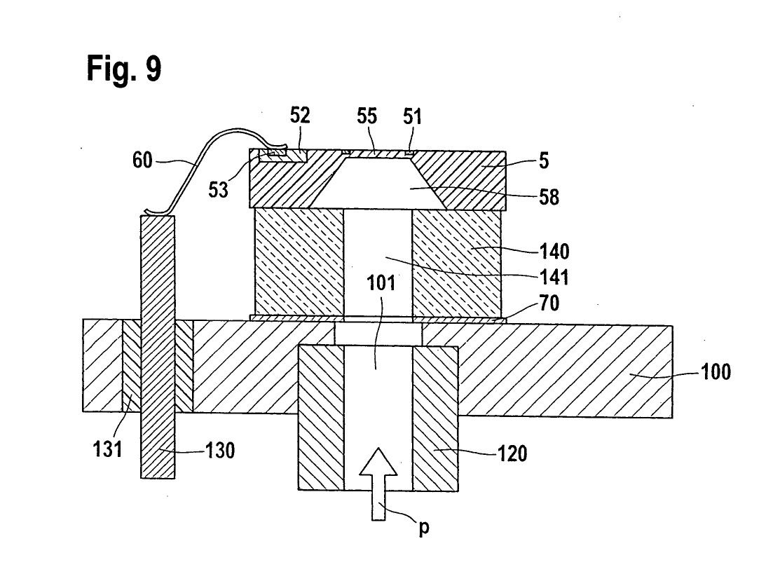

FIG. 8a-g show successive method steps of an eighth example embodiment of the method according to the present invention for packaging semiconductor chips in a cross-sectional view.

In the manufacturing method according to FIG. 8, prior to mounting semiconductor chip 5 on leadframe 1 and prior to providing molded housing 20, 20a through 20f, a subassembly BG is formed, including semiconductor chip 5, cap 10, 10a through 10g provided over diaphragm region 55, and a glass base 140 which is secured to the back side of the periphery of diaphragm region 55.

According to FIG. 8a, b and d, to that end, first of all a sensor wafer SW having a plurality-of semiconductor chips 5 with cavities 58 and optionally a respective circuit (not shown) is made available in the composite construction. Moreover, a cap wafer KW having a corresponding plurality of caps 10, 10a through 10g is made available in the composite construction. In addition, a glass-base wafer GSW having a corresponding plurality of glass bases 140 is made available in the composite construction. An optional metallization layer M is located on the back side of glass-base wafer GSW and cap wafer KW.

In the process step shown in FIGS. 8c and 8e, respectively, sensor wafer SW, cap wafer KW and glass-base wafer GSW are joined to each other in order to produce a plurality of subassemblies BG in the composite construction.

Depressions V, V′ are provided on cap wafer KW, depressions V coming to rest above diaphragm regions 55 where they form hollow spaces 65g, and depressions V′ coming to rest and forming hollow spaces H above side edge regions 59 of sensor chips 5, side edge regions 59 projecting laterally beyond caps 10, 10a through 10g and having respective bonding regions 53.

According to FIG. 8f, hollow spaces H have the function that, when sawing, initially a first sawing step may be carried out in which cap wafer KW is sawed above hollow spaces H for exposing bonding regions 53. In a second sawing step, sensor wafer SW and glass-base wafer GSW are then sawed below hollow spaces H for separating the subassemblies. In so doing, the saw-cut width should be greater in the first sawing step than in the second sawing step. Care should merely be taken that the distance between sensor chip 5 and cap 10 is selected to be sufficiently large that, taking into consideration the saw cut depth tolerance, damage to the chips is avoided during the first sawing step. After the second sawing step, separated subassemblies BG are obtained as shown in FIG. 8g.

Although the present invention has been explained above in light of preferred specific embodiments, it is not limited to, them, but may also be executed in other ways.

Optionally, to minimize the mechanical stresses at the lower side of sensor chip 5, the silicon at the lower side may be porously etched. To further reduce the mechanical stresses acting on sensor chip 5, leadframe 1 may also be suitably structured or implemented as a combi-leadframe.

A further variant (not shown) is yielded when a surface-mechanical sensor is to be used. In these sensors, a hollow space is produced on the front side, e.g., through porous silicon, which is produced before an epitaxy layer in the region of the diaphragm and is rearranged during the epitaxy process in such a way that a hollow space develops. In such a sensor, glass base 140 may be omitted, since the reference volume is located in the chip itself.

Pressure connecting pieces 90, 92 may be applied on leadframe 1 by adhesive bonding or soldering. Alternatively, the pressure connecting pieces may also be formed by injection molding during the molding process, by injecting from above or below. The groove for a sealing ring (O-ring) may also be introduced around the pressure connecting pieces during the molding process.

In the above example, only piezoresistive sensor structures were examined. However, the present invention is also suitable for capacitive or other sensor structures, in which diaphragms are used.

1. A method for packaging a semiconductor chip, comprising:
making available a semiconductor chip having a diaphragm region;
providing a cap over the diaphragm region, while leaving the diaphragm region open;
mounting the semiconductor chip on a support frame; and
providing a molded housing around the semiconductor chip and at least a partial area of the support frame for packaging the semiconductors chip.

2. The method as recited in claim 1, wherein the cap is applied using glass solder in a periphery of the diaphragm region in such a way that a closed hollow space is formed between the cap and the diaphragm region.

3. The method as recited in claim 1, wherein the cap has a through hole, and the molded housing is provided in such a way that a through hole in the molded housing joins up with the through hole in the cap.

4. The method as recited in claim 1, wherein the semiconductor chip is mounted on the support frame on a side opposite the diaphragm region.

5. The method as recited in claim 4, wherein the support frame has a through hole which creates a connection to a cavity region below the diaphragm region, and the molded housing is provided in such a way that a through hole in the molded housing joins up with the through hole in the support frame.

6. The method as recited in claim 1, wherein the semiconductor chip is mounted on the support frame via a glass base that is secured on a back side of the periphery of a diaphragm region.

7. The method as recited in claim 1, wherein the semiconductor chip has a side edge region that projects laterally beyond the cap and has a bonding region which is electrically connected to the support frame via a bonding wire, after which the bonding wire is completely packaged in the molded housing.

8. The method as recited in claim 1, wherein the cap has a through hole at which a connecting piece is mounted, and the molded housing is provided in such a way that the connecting piece is partially packaged in the molded housing.

9. The method as recited in claim 1, wherein the support frame has a through hole that creates a connection to a cavity region below the diaphragm region and at which a connecting piece is mounted, and the molded housing is provided in such a way that the connecting piece is partially packaged in the molded housing.

10. The method as recited in claim 1, wherein the semiconductor chip is mounted via the cap on the support frame.

11. The method as recited in claim 1, wherein prior to mounting the semiconductor chip on the support frame and prior to providing the molded housing, a subassembly is formed including the semiconductor chip, the cap provided over the diaphragm region, and a glass base that is secured on a back side of a periphery of the diaphragm region.

12. The method as recited in claim 11, wherein the subassembly is formed by the following steps:
making available a first wafer having a plurality of semiconductor chips in a composite construction;
making available a second wafer having a corresponding plurality of caps in the composite construction;
making available a third wafer having a corresponding plurality of glass bases in the composite construction;
joining the first wafer, the second wafer and the third wafer to produce a plurality of subassemblies in the composite construction; and
separating the subassemblies.

13. The method as recited in claim 12, wherein the second wafer has a plurality of hollow spaces which, in joining the first wafer and the second wafer, leave open side edge regions that project laterally beyond the caps and have respective bonding regions; and for separating the subassemblies, in a first sawing step, the second wafer is sawed over the hollow spaces for exposing the bonding regions, and in a second sawing step, the first wafer and the third wafer are sawed below the hollow spaces for separating the subassemblies, a larger saw-cut width being used in the first sawing step than in the second sawing step.

14. A semiconductor chip system, comprising:
a semiconductor chip having a diaphragm region;
a cap mounted over the diaphragm region, while leaving the diaphragm region open;
a support frame, on which the semiconductor chip is mounted; and
a molded housing around the semiconductor chip and at least a partial area of the support frame for packaging the semiconductor chip.

15. The semiconductor chip system as recited in claim 14, further comprising:
glass solder, the cap being applied using the glass solder in a periphery of the diaphragm region in such a way that a closed hollow space is formed between the cap and the diaphragm region.

16. The semiconductor chip system as recited in claim 14, wherein the cap has a through hole, and the molded housing is provided in such a way that a through hole in the molded housing joins up with the through hole in the cap.

17. The semiconductor chip system as recited in claim 14, wherein the semiconductor chip is mounted on the support frame on a side opposite the diaphragm region.

18. The semiconductor chip system as recited in claim 17, wherein the support frame has a through hole which creates a connection to a cavity region below the diaphragm region, and the molded housing is provided in such a way that a through hole in the molded housing joins up with the through hole in the support frame.

19. The semiconductor chip system as recited in claim 14, wherein the semiconductor chip is mounted on the support frame via a glass base that is secured on a back side of the periphery of a diaphragm region.

20. The semiconductor chip system as recited in claim 14, wherein the semiconductor chip has a side edge region that projects laterally beyond the cap and has a bonding region which is electrically connected to the support frame via a bonding wire, and the bonding wire is completely packaged in the molded housing.

21. The semiconductor chip system as recited in claim 14, wherein the cap has a through hole at which a connecting piece is mounted, and the molded housing is provided in such a way that the connecting piece is partially packaged in the molded housing.

22. The semiconductor chip system as recited in claim 14, wherein the support frame has a through hole that creates a connection to a cavity region below the diaphragm region and at which a connecting piece is mounted, and the molded housing is provided in such a way that the connecting piece is partially packaged in the molded housing.

23. The semiconductor chip system as recited in claim 14, wherein the semiconductor chip is mounted via the cap on the support frame.

24. The semiconductor chip system as recited in claim 14, wherein the support frame is a leadframe.
